(19) United States
(12) Patent Application Publication
(10) Pub. No.: US 2019/0259650 A1
(43) Pub. Date: Aug. 22, 2019

(54) METHOD FOR PROTECTING COBALT PLUGS

(71) Applicant: Tokyo Electron Limited, Tokyo (JP)

(72) Inventors: Sang Cheol Han, Albany, NY (US); Soo Doo Chae, Albany, NY (US); Kai-Hung Yu, Albany, NY (US)

(21) Appl. No.: 16/277,744

(22) Filed: Feb. 15, 2019

Related U.S. Application Data
(60) Provisional application No. 62/632,997, filed on Feb. 20, 2018.

(51) Int. Cl. H01L 21/768; H01L 23/522; H01L 21/285; H01L 21/3213; H01L 21/02; H01L 23/532; C23C 16/06; C23C 16/56

(52) U.S. Cl. CPC H01L 21/7685; H01L 23/5226; H01L 21/28568; H01L 21/32136; C23C 16/56; H01L 23/53209; H01L 23/53242; H01L 21/76861; C23C 16/06; H01L 21/02068

(57) ABSTRACT

Methods are described for protecting cobalt (Co) metal plugs used for making electrical connections within a semiconductor device. In one example, method includes providing a substrate containing a Co metal plug in a dielectric layer, and selectively forming a ruthenium (Ru) metal cap layer on the Co metal plug. In another example, the method includes providing a substrate containing a Co metal plug in a first dielectric layer, selectively forming a Ru metal cap layer on the Co metal plug, depositing a second dielectric layer on the Ru metal cap layer and on the first dielectric layer, etching a recessed feature in the second dielectric layer to expose the Ru metal cap layer, and performing a cleaning process that removes polymer etch residue from the Ru metal cap layer in the recessed feature.

### CROSS-REFERENCE TO RELATED APPLICATIONS

This application is related to and claims priority to U.S. Provisional Patent Application Ser. No. 62/632,997 filed on Feb. 20, 2018, the entire contents of which are herein incorporated by reference.

### FIELD OF THE INVENTION

The present invention relates to methods for manufacturing semiconductor devices, and more particularly, to methods for protecting cobalt (Co) plugs used for making electrical connections within a semiconductor device.

### BACKGROUND OF THE INVENTION

An integrated circuit contains various semiconductor devices and a plurality of conducting metal paths that provide electrical power to the semiconductor devices and allow the semiconductor devices to share and exchange information. Within the integrated circuit, metal layers are stacked on top of one another using intermetal and interlayer dielectric layers (ILDs) that insulate the metal layers from each other.

Normally, each metal layer must form an electrical contact to at least one additional metal layer. Such electrical contact is achieved by etching a feature (i.e., a via) in the interlayer dielectric layer that separates the metal layers, and filling the resulting via with a metal to create an interconnect. A “via” normally refers to any feature such as a hole, line or other similar feature formed within a dielectric layer that provides an electrical connection through the dielectric layer to a conductive layer underlying the dielectric layer. Similarly, metal layers connecting two or more vias are normally referred to as trenches.

An increase in device performance is normally accompanied by a decrease in device area or an increase in device density. An increase in device density requires a decrease in via dimensions used to form interconnects, including a larger aspect ratio (i.e., depth to width ratio). Copper (Cu) metal is commonly used in multilayer metallization schemes for manufacturing advanced integrated circuits. Problems associated with the use of Cu metal in increasingly smaller features in a substrate will require replacing the Cu metal with other low-resistivity metals.

Co metal is a low-resistivity metal that may replace Cu metal for making electrical connections within a semiconductor device. During device manufacturing, etch residue may be removed from a Co metal layer by wet etching using a solvent. However, the etch residue can become dissolved in the solvent and thereafter the solvent can chemically attack and erode the Co metal layer to form a void defect in the Co metal layer. The void defect formation in Co metal plugs needs to be avoided. Methods are therefore needed for protecting Co metal plugs and preventing the formation of void defects in the Co metal plugs in semiconductor devices.

### SUMMARY OF THE INVENTION

Methods are provided for protecting Co metal plugs used for making electrical connections within a semiconductor device. According to one embodiment, the method includes providing a substrate containing a Co metal plug in a dielectric layer, and selectively forming a ruthenium (Ru) metal cap layer on the Co metal plug.

According to another embodiment, the method includes providing a substrate containing a Co metal plug in a first dielectric layer, selectively forming a Ru metal cap layer on the Co metal plug, depositing a second dielectric layer on the Ru metal cap layer and on the first dielectric layer, etching a recessed feature in the second dielectric layer to expose the Ru metal cap layer, and performing a cleaning process that removes polymer etch residue from the Ru metal cap layer in the recessed feature.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1A-1F schematically show through cross-sectional views a method of processing a substrate according to an embodiment of the invention.

### DETAILED DESCRIPTION OF SEVERAL EMBODIMENTS

Methods for processing a substrate are described in several embodiments. According to one embodiment, the method includes providing a substrate containing a Co metal plug in a dielectric layer, and selectively forming a Ru metal cap layer on the Co metal plug. According to another embodiment, the method includes providing a substrate containing a Co metal plug in a first dielectric layer, selectively forming a Ru metal cap layer on the Co metal plug, depositing a second dielectric layer on the Ru metal cap layer and on the first dielectric layer, etching a recessed feature in the second dielectric layer to expose the Ru metal cap layer, and performing a cleaning process that removes polymer etch residue from the Ru metal cap layer in the recessed feature.

Embodiments of the invention may be applied to a variety of recessed features of different physical shapes found in semiconductor devices, including square recessed features with vertical sidewalls, bowed recessed features with convex sidewalls, recessed features with V-shaped sidewalls, and recessed features with a sidewall having an area of retrograde profile relative to a direction extending from a top of the recessed features to the bottom of the recessed features. The recessed features can, for example, include a trench or a via.

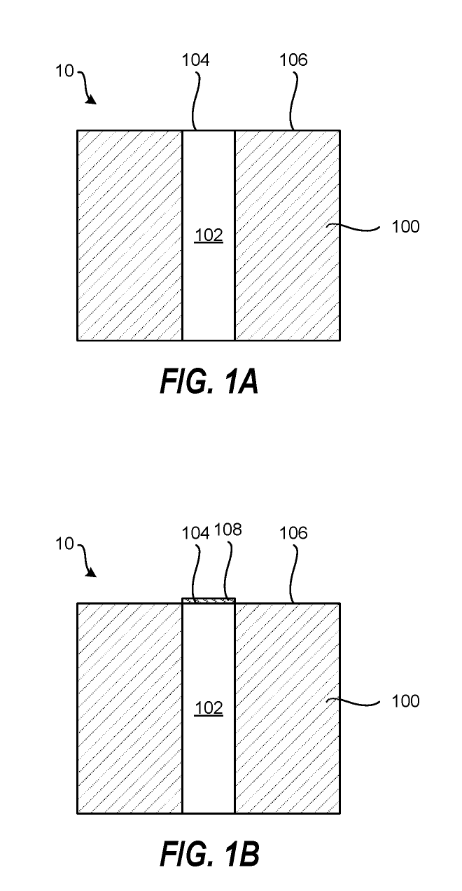

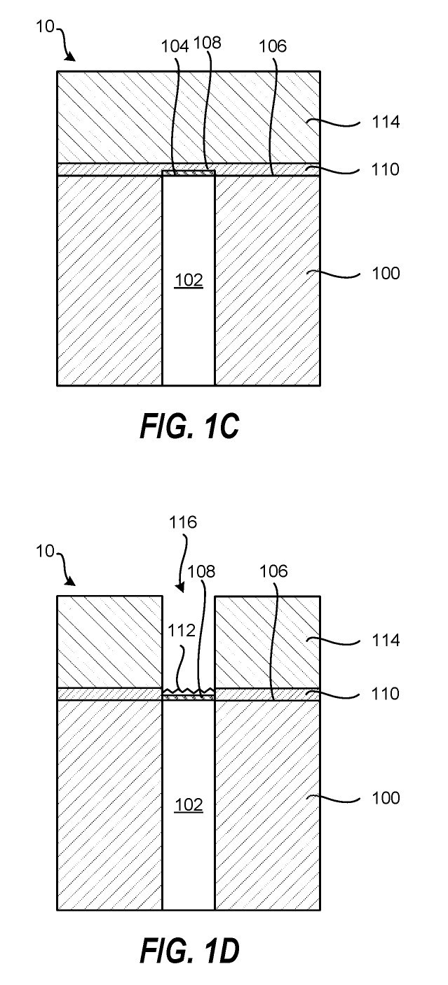

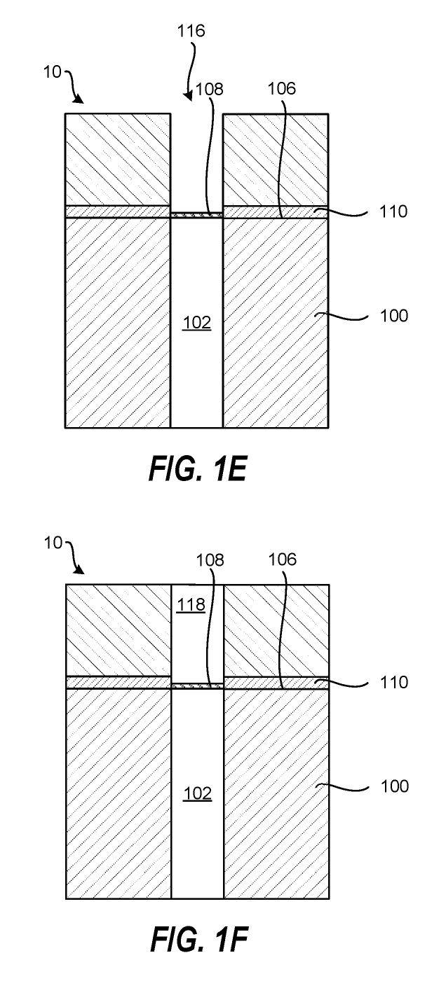

FIGS. 1A-1F schematically show through cross-sectional views a method of processing a substrate according to an embodiment of the invention. FIG. 1A shows a planarized substrate 10 containing a first dielectric layer 100 having an exposed surface 106 and a Co metal plug 102 having an exposed surface 104. The Co metal plug 102 provides an electrical connection through the first dielectric layer 100 to a conductive layer (not shown) underlying the first dielectric layer 100. The first dielectric layer 100 may be selected from the group consisting of SiO₂, SiON, SiN, a high-k material, a low-k material, and an ultra-low-k material.

FIG. 1B shows a Ru metal cap layer 108 that is selectively formed on the exposed surface 104 of the Co metal plug 102. According to one embodiment, the Ru metal cap layer 108 may be deposited by atomic layer deposition (ALD) or chemical vapor deposition (CVD). In one example, the Ru metal cap layer 108 may be deposited by CVD using Ru₃(CO)₁₂ and CO carrier gas at a substrate temperature of about 200° C. However, other Ru metal precursors may be used that provide selective formation of the Ru metal cap layer 108 on the surface 104 of the Co metal plug 102.

According to one embodiment, the process of depositing the Ru metal cap layer 108 may further deposit a small amount of unwanted additional Ru metal (not shown) on the exposed surface 106 of the first dielectric layer 100. In one example, the loss of Ru metal deposition selectivity on the Co metal plug 102 may occur if the duration of the Ru metal deposition exceeds a time period where Ru metal deposition is selective on the Co metal plug 102. In another example, the loss of deposition selectivity may occur due to the presence of nucleation sites on the exposed surface 106 of the first dielectric layer 100.

The additional Ru metal may be removed from the surface 106 to selectively form the Ru metal cap layer 108 on the Co metal plug 102. According to one embodiment, removing the additional Ru metal can include exposing the substrate 10 to a plasma-excited dry etching process. The plasma-excited dry etching process can include a chemical reaction between a plasma-excited etching gas and the additional Ru metal, physical removal of the additional Ru metal by a non-reactive gas, or a combination thereof. In one example, the plasma-excited dry etching process includes exposing the substrate 10 to a plasma-excited etching gas containing an oxygen-containing gas and optionally a halogen-containing gas. In another example, the removing can include sputter removal of the additional Ru metal using a plasma-excited Ar gas. According to yet another embodiment, the removing can include a combination of a plasma-excited dry etching process and heat-treating. Exemplary processing conditions for a plasma-excited dry etching process include a gas pressure between about 5 mTorr and about 760 mTorr, and a substrate temperature between about 40° C. and about 370° C. A capacitively coupled plasma (CCP) processing system containing a top electrode plate and a bottom electrode plate supporting a substrate may be used. In one example, radio frequency (RF) power between about 100 W and about 1500 W may be applied to the top electrode plate. RF power may also be applied to the bottom electrode plate to increase Ru metal removal.

According to one embodiment, the plasma-excited etching gas can contain an oxygen-containing gas and optionally a halogen-containing gas to enhance the Ru metal removal. The oxygen-containing gas can include O₂, H₂O, CO, CO₂, and a combination thereof. The halogen-containing gas can, for example, include Cl₂, BCl₃, CF₄, and a combination thereof In one example, the plasma-excited etching gas can include O₂ and Cl₂. The plasma excited etching gas can further include Ar gas. In some embodiments, flows of the one or more gases in the plasma-excited etching gas may be cycled.

FIG. 1C shows an optional etch stop layer 110 that may be formed on the Ru metal cap layer 108 and on the exposed surface 106 of the first dielectric layer 100. The optional etch stop layer 110 may contain one or more sublayers with different chemical compositions. In one example, the optional etch stop layer 110 can contain one or more of SiN, SiO₂, and SiON. A second dielectric layer 114 is formed on the substrate 10. The second dielectric layer 114 may be selected from the group consisting of SiO₂, SiON, SiN, a high-k material, a low-k material, and an ultra-low-k material.

FIG. 1D shows a recessed feature 116 formed in the second dielectric layer 114. The recessed feature 116 may be formed using well-known lithography and etching methods. The etching methods may include RIE that can form a polymer etch residue 112 (e.g., CFₓ—R) in the recessed feature 116, including on the Ru metal cap layer 108 and on the sidewalls of the recessed feature 116 (not shown). The polymer etch residue 112 may be removed in a cleaning process by wet etching using a solvent, for example DI water. The Ru metal cap layer 108 has high chemical resistance to etching by many common solvents and the polymer etch residue dissolved in the solvent, thereby protecting the underlying Co metal plug 102 during the cleaning process. Thus, Co metal dissolution and void defect formation is avoided in the Co metal plug 102. The use of the Ru metal cap layer 108 to protect the Co metal plug 102 has several advantages over other protection methods including 1) heat budget issues are avoided since no annealing of the substrate is needed, 2) simple and few processing steps needed, 3) reduction or absence of defects in the Co metal plug 102, and 4) low electrical resistivity of the Ru metal cap layer 108.

Further processing of the substrate 10 can include filling the recessed feature 116 with a metallization layer 118, e.g., Ru metal, Co metal, or Cu metal. This is schematically shown in FIG. 1F. The Ru metal cap layer 108 provides an excellent growth surface for depositing the metallization layer 118 in the recessed feature 116. According to another embodiment, the Ru metal cap layer 108 may be removed prior to filling the recessed feature 116 with the metallization layer 118.

Methods for protecting Co metal plugs used for making electrical connections within a semiconductor device have been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

1. A substrate processing method, comprising:
providing a substrate containing a cobalt (Co) metal plug in a dielectric layer; and
selectively forming a ruthenium (Ru) metal cap layer on the Co metal plug.

2. The method of claim 1, wherein the selectively forming the Ru metal cap layer on the Co metal plug includes exposing the substrate to a process gas containing Ru₃(CO)₁₂ gas and CO gas.

3. The method of claim 1, wherein the selectively forming the Ru metal cap layer on the Co metal plug includes
depositing the Ru metal cap layer on the Co metal plug;
depositing additional Ru metal on the dielectric layer; and
removing the additional Ru metal from the dielectric layer.

4. The method of claim 3, wherein the depositing the Ru metal cap layer and the depositing the additional Ru metal includes exposing the substrate to a process gas containing Ru₃(CO)₁₂ gas and CO gas.

5. The method of claim 3, wherein the removing the additional Ru metal from the dielectric layer includes exposing the substrate to a plasma-excited dry etching process.

6. The method of claim 1, wherein the substrate is planarized and includes a surface of the Co metal plug and a surface of the dielectric layer in the same plane.

7. The method of claim 1, wherein the dielectric layer includes a low-k material.

8. A substrate processing method, comprising:
providing a substrate containing a cobalt (Co) metal plug in a first dielectric layer;
selectively forming a ruthenium (Ru) metal cap layer on the Co metal plug;
depositing a second dielectric layer on the Ru metal cap layer and on the first dielectric layer;
etching a recessed feature in the second dielectric layer to expose the Ru metal cap layer; and
performing a cleaning process that removes polymer etch residue from the Ru metal cap layer in the recessed feature.

9. The method of claim 8, wherein the selectively forming the Ru metal cap layer on the Co metal plug includes
depositing the Ru metal cap layer on the Co metal plug;
depositing additional Ru metal on the first dielectric layer; and
removing the additional Ru metal from the first dielectric layer.

10. The method of claim 9, wherein the depositing the Ru metal cap layer and the depositing the additional Ru metal includes exposing the substrate to a process gas containing Ru₃(CO)₁₂ gas and CO gas.

11. The method of claim 9, wherein the removing the additional Ru metal from the first dielectric layer includes exposing the substrate to a plasma-excited dry etching process.

12. The method of claim 11, wherein the plasma-excited dry etching process includes an oxygen-containing gas and optionally a halogen-containing gas

13. The method of claim 8, wherein the substrate is planarized and includes a surface of the Co metal plug and a surface of the first dielectric layer in the same plane.

14. The method of claim 8, further comprising:
prior to depositing the second dielectric layer, forming an etch stop layer on the Ru metal cap layer.

15. The method of claim 8, wherein the first and second dielectric layers are selected from the group consisting of SiO₂, SiON, SiN, a high-k material, a low-k material, and an ultra-low-k material

16. The method of claim 8, wherein the first and second dielectric layers include a low-k material.

17. The method of claim 8, wherein the etching includes anisotropic gaseous etching.

18. The method of claim 8, wherein the cleaning process includes a wet etching process.

19. The method of claim 18, wherein the wet etching process includes DI water.

20. The method of claim 8, wherein the polymer etch residue originates from the etching of the recessed feature in the second dielectric layer.
